(19) United States
(12) Patent Application Publication
(10) Pub. No.: US 2019/0150328 A1
(43) Pub. Date: May 16, 2019

(54) POWER CONTROL DEVICE AND STRUCTURE OF MOUNTING THE SAME

(71) Applicant: TOYOTA JIDOSHA KABUSHIKI KAISHA, Toyota-shi (JP)

(72) Inventors: Shinichi MIURA, Toyota-shi (JP); Yutaka MORIMOTO, Toyokawa-shi (JP); Hiromi YAMASAKI, Toyota-shi (JP); Hitoshi IMURA, Chiryu-shi (JP)

(73) Assignee: TOYOTA JIDOSHA KABUSHIKI KAISHA, Toyota-shi (JP)

(21) Appl. No.: 16/148,408

(22) Filed: Oct. 1, 2018

(30) Foreign Application Priority Data
Nov. 14, 2017 (JP) 2017-219101

(51) Int. Cl. H05K 7/20; H05K 5/03; H05K 5/00; B60R 16/03

(52) U.S. Cl. CPC H05K 7/20872; H05K 7/20927; B60R 16/03; H05K 5/0004; H05K 5/0017; H05K 5/03

(57) ABSTRACT

A power control device includes a cooling medium flow channel provided on a lower portion of a casing of the power control device; a cover attached to a lower surface of the casing with a gasket interposed between the cover and the lower surface, the gasket surrounding the cooling medium flow channel, the cover closing the cooling medium flow channel; and a groove or a protrusion provided on the lower surface at a position between the gasket and an outer edge of the lower surface.

### CROSS-REFERENCE TO RELATED APPLICATION

This application claims priority to Japanese Patent Application No. 2017-219101 filed on Nov. 14, 2017, the contents of which are hereby incorporated by reference into the present application.

### TECHNICAL FIELD

The technique disclosed herein relates to a power control device for controlling electric power supplied to an electric traction motor for a vehicle and a vehicle-mounted structure of the power control device.

### BACKGROUND

An electric vehicle is equipped with a power control device that controls electric power supplied to an electric traction motor (hereinafter referred to as “a traction motor”). The power control device includes a cooler using a liquid cooling medium in order to handle a large amount of electric power. In addition, there is a possibility that water droplets adhere to the power control device mounted on a vehicle, and hence a casing of the power control device is required to have water resistance.

Japanese Patent Application Publication No. 2016-111250 (Patent Document 1) describes a power control device that has a cooling medium flow channel provided in a lower portion of a casing. A gasket is disposed on a lower surface of the casing so as to surround a periphery of the cooling medium flow channel. A cover is attached to the lower surface of the casing with the gasket interposed between the cover and the lower surface so as to seal the cooling medium flow channel.

In the power control device disclosed in Japanese Patent Application Publication No. 2016-076511, a groove for guiding leaking water is provided between the cooling medium flow channel and an electric component arranged at a position lower than the cooling medium flow channel so that water leaking from the cooling medium flow channel does not adhere to the electric component inside the casing.

### SUMMARY

In the power control device described in Patent Document 1, the cover closing the cooling medium flow channel is attached to the lower surface of the casing with the gasket interposed between the cover and the lower surface. The gasket is slightly exposed between the cover and the lower surface of the casing. If water (or salt water) moving on lateral surfaces of the casing travels along the lower surface of the casing and adheres to the gasket, corrosion of the gasket or the cover might progress from that point of adhesion. The present disclosure provides a technique for preventing water from adhering to a gasket in a power control device in which a cover for closing a cooling medium flow channel is attached to a lower surface of a casing with a gasket interposed between the cover and the lower surface.

A power control device disclosed herein may comprise a cooling medium flow channel provided on a lower portion (lower surface) of a casing of the power control device; a cover attached to a lower surface of the casing with a gasket interposed between the cover and the lower surface, the gasket surrounding the cooling medium flow channel, the cover closing the cooling medium flow channel; and a groove or a protrusion provided on the lower surface at a position between the gasket and an outer edge of the lower surface.

The groove or protrusion is located between the gasket and an outer edge of the lower surface. Water traveling from a lateral surface to the lower surface of the casing drops at an edge of the groove and cannot overcome the groove. Alternatively, water traveling from lateral surfaces to the lower surface of the casing drops at a top surface of the protrusion and cannot overcome the protrusion. Thus, the water is prevented from adhering to the gasket. The groove or protrusion may be provided at least between the gasket and a back edge of the lower surface. The groove or protrusion may be further provided between the gasket and either or each of the left and right outer edges of the lower surface. In this case, water traveling from either or each of the left and right lateral surfaces of the casing to the lower surface can be prevented from adhering to the gasket.

A structure of mounting the above power control device is disclosed herein. In the structure, the power control device may be mounted in a front compartment of a vehicle, and the groove or the protrusion may be provided on the lower surface at a position between the gasket and the outer edge of the lower surface on a back side of the casing in a front and back direction of the vehicle.

In the front compartment of the vehicle, water (or salt water) splashes up from between side members or between cross members and may be scattered just toward the back side of the casing in the power control device. Thus, when the groove on the lower surface of the casing is provided between the gasket and the outer edge of the lower surface on the back side of the casing, water can be effectively prevented from splashing up and traveling from the lateral surfaces (back surface) of the casing to the lower surface thereof.

### BRIEF DESCRIPTION OF DRAWINGS

FIG. 1 is a perspective view of a power control device according to an embodiment;

FIG. 2 is a perspective view of the power control device according to the embodiment as viewed obliquely from below;

FIG. 3 is a cross-sectional view along a line in FIG. 1;

FIG. 4 is an enlarged view of a range IV shown in FIG. 3;

FIG. 5 is a partially enlarged view of a cross-sectional portion of a power control device according to a variant;

FIG. 6 is a plan view of a front compartment in which the power control device is mounted;

FIG. 7 is a side view of the power control device fixed on a transaxle; and

FIG. 8 is a perspective view of a power control device according to another variant as viewed obliquely from below.

### DETAILED DESCRIPTION

Representative, non-limiting examples of the present invention will now be described in further detail with reference to the attached drawings. This detailed description is merely intended to teach a person of skill in the art further details for practicing preferred aspects of the present teachings and is not intended to limit the scope of the invention. Furthermore, each of the additional features and teachings disclosed below may be utilized separately or in conjunction with other features and teachings to provide improved a power control device and a structure of mounting the same.

Moreover, combinations of features and steps disclosed in the following detailed description may not be necessary to practice the invention in the broadest sense, and are instead taught merely to particularly describe representative examples of the invention. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

### Embodiments

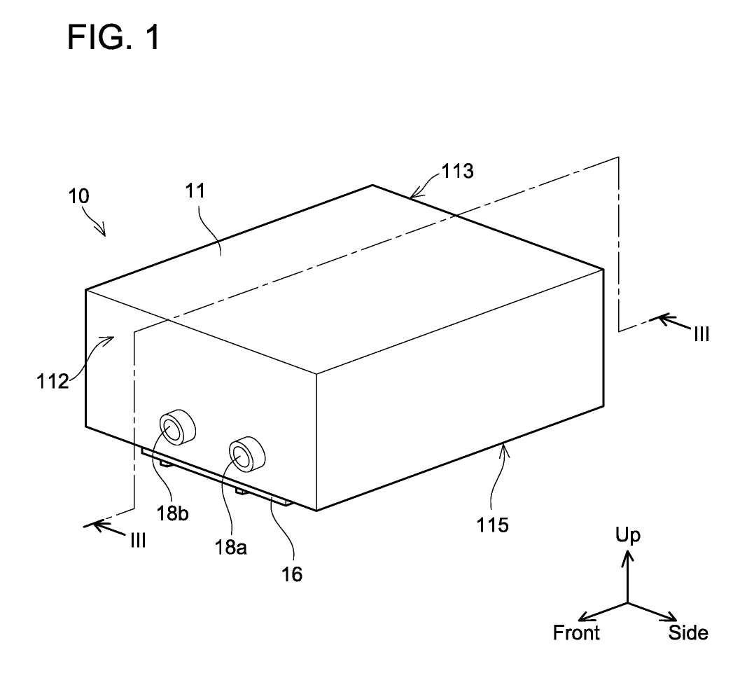

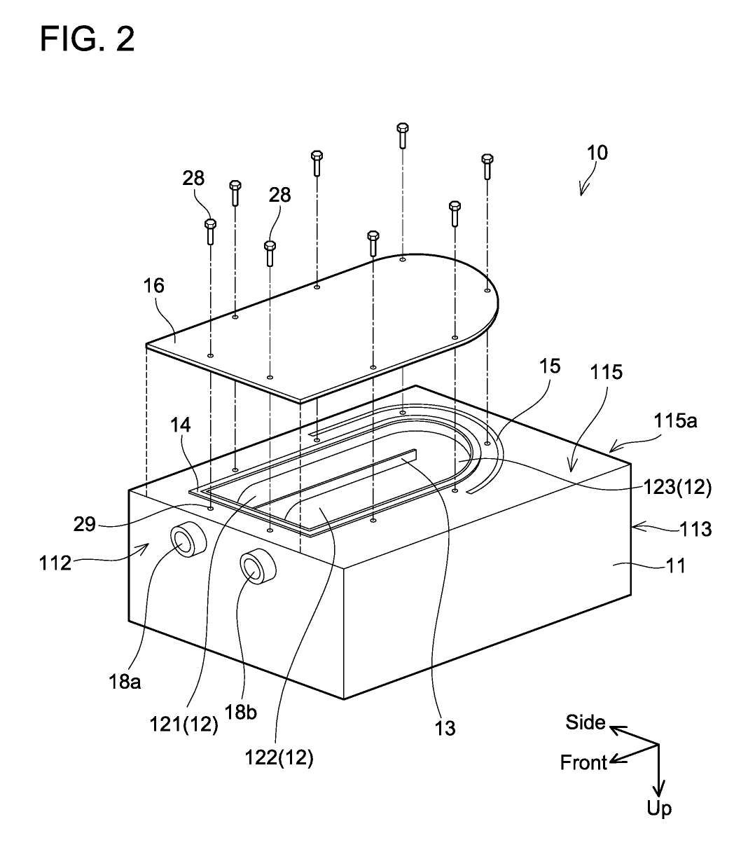

A power control device 10 of an embodiment will be described below with reference to attached drawings. FIG. 1 is a perspective view of the power control device 10. FIG. 2 is a perspective view of the power control device 10 as viewed obliquely from below. FIG. 2 is the view of the power control device 10 from which a lower cover 16 is removed.

The power control device 10 of the embodiment is a device that is to be mounted on a hybrid vehicle and configured to control a driving electric power of an electric traction motor of the vehicle. A coordinate system Front/Up/Side in the drawings means a Front/Up/Side direction of the vehicle when the power control device 10 is mounted on the hybrid vehicle. It should be noted that a downward direction in FIG. 2 means the Up direction.

A casing 11 of the power control device 10 includes, in its lower portion, a flow channel (cooling medium flow channel 12) through which a cooling medium flows (see FIG. 2). The cooling medium flow channel 12 is provided on an outer lower surface 115 of the casing 11. The coolant medium flow channel 12 is divided into two passages, namely, a supply passage 121 and a discharge passage 122 in a lateral direction (Side direction) by a partition plate 13. The supply passage 121 communicates with a supply port 18a provided in a front surface 112 of the casing 11, and the discharge passage 122 communicates with a discharge port 18b provided in the front surface 112. The partition plate 13 extends from a front side toward a back side, and ends midway. The supply passage 121 and the discharge passage 122 are connected together by a U-turn portion 123 at a back portion of the cooling medium flow channel 12. A cooling medium circulation device (not shown) is connected to the supply port 18a and the discharge port 18b, so that the cooling medium is supplied from the supply port 18a. The cooling medium supplied from the supply port 18a passes through the supply passage 121, the U-turn portion 123, and the discharge passage 122, and is then discharged from the discharge port 18b. The cooling medium may be a liquid, such as water or a Long Life Coolant (LLC). Inside the casing 11, an electric component that potentially generates a large amount of heat is disposed to face the cooling medium flow channel 12. The heat generated from the electric component is absorbed in the cooling medium that passes through the cooling medium flow channel 12.

The cooling medium flow channel 12 provided in a lower portion (lower surface 115) of the casing 11 has its lower side (bottom of the cooling medium flow channel 12) opened. A gasket 14 is disposed on the lower surface 115 of the casing 11 so as to surround the cooling medium flow channel 12. The opened bottom surface of the cooling medium flow channel 12 is covered with the lower cover 16. The lower cover 16 is attached to the lower surface 115 of the casing 11 with the gasket 14 interposed between the lower cover 16 and the lower surface 115. The lower cover 16 is attached to the lower surface 115 by a plurality of bolts 28. A plurality of bolt holes 29 into which the bolts 28 are screwed is provided in the lower surface 115 of the casing 11 so as to surround the cooling medium flow channel 12 and the gasket 14.

The gasket 14 may be a metal gasket or a rubber gasket. Alternatively, the gasket 14 may be a Formed In Place Gasket (FIPG).

A groove 15 is provided in the lower surface 115 of the casing 11 so as to extend along an outer periphery of the gasket 14. The groove 15 is located between the gasket 14 and an outer edge 115a of a back portion of the lower surface 115. The groove 15 is provided on the back side of the casing 11 in the front and back direction of the vehicle. In other words, the groove 15 is provided in the lower surface 115 so as to surround the back portion of the gasket 14.

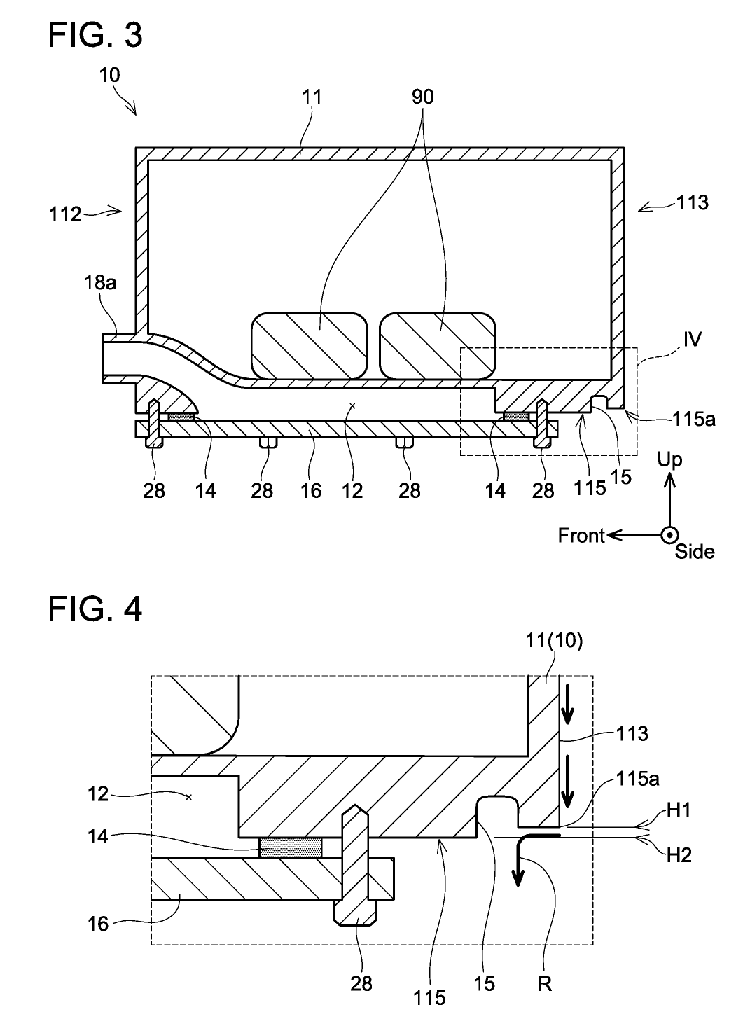

FIG. 3 shows a cross-sectional view along a line in FIG. 1. The cross-sectional view of FIG. 3 is a cross-sectional view cut along a plane including the Front axis and the Up axis of the coordinate system shown and passing through the supply port 18a. As mentioned above, electric components 90 are disposed to face the cooling medium flow passage 12 within the casing 11. The electric components 90 are, for example, a reactor or a capacitor. Further, as mentioned above, the groove 15 is provided in the lower surface 115 of the casing 11. The groove 15 is disposed between the gasket 14 and the outer edge 115a of the back portion of the lower surface 115. Hereinafter, the outer edge 115a of the back portion will be simply referred to as the “outer edge 115a”.

A function of the groove 15 will be described below. The power control device 10 is mounted in the front compartment of the vehicle. Water (or salt water) splashed during driving may enter the front compartment. If a large amount of water (or salt water) adheres to and accumulates in the gasket 14 interposed between the lower surface 115 and the cover 16, corrosion might progress into the gasket 14 and its surroundings. Because of this, it is desirable that the adhesion of water (or salt water) to the gasket 14 is prevented. FIG. 4 shows an enlarged view of a range indicated by a dashed line IV in FIG. 3. For example, water droplets that adhere to a back surface 113 of the casing 11 travel from the back surface 113 to the lower surface 115. However, water droplets that have reached the lower surface 115 are blocked by the groove 15 and then fall. In FIG. 4, thick arrow lines R schematically represent a path of the water droplets. The water droplets that have reached the lower surface 115 are blocked by the groove 15 and then fall, and consequently do not reach the gasket 14. The groove 15 prevents the water droplets that have traveled from the back surface 113 or lateral surfaces of the casing 11 to the lower surface 115 from reaching the gasket 14.

A height H1 of the lower surface 115 on an outer edge 115a side from the groove 15 may be higher than a height H2 of the lower surface 115 on a gasket 14 side from the groove 15. If the lower surface height H1 on the outer edge 115a side from the groove 15 is higher than the lower surface height H2 on the gasket 14 side, it is advantageous for manufacturing the casing 11 by injection molding.

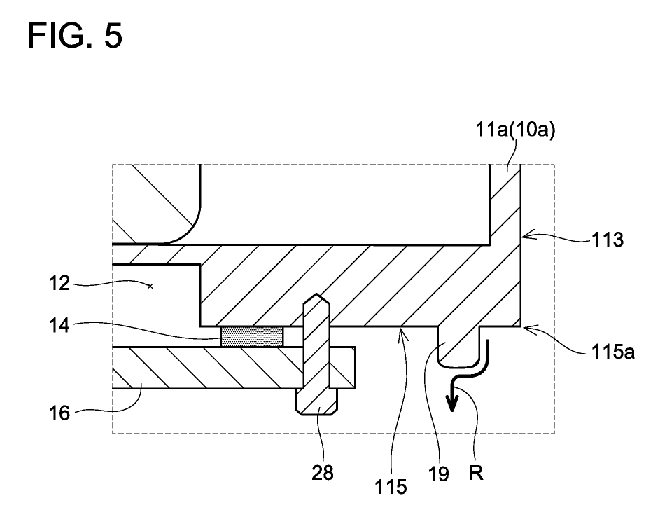

FIG. 5 is a partially enlarged view of a cross-sectional portion of a power control device 10a according to a variant. The enlarged view of FIG. 5 corresponds to an enlarged view of FIG. 4. The power control device 10a includes a protrusion 19 in place of the groove 15 in a casing 11a. Like the groove 15, the protrusion 19 is provided on the lower surface 115. The protrusion 19 is provided between the gasket 14 and the outer edge 115a of the lower surface 115. Like the groove 15, the protrusion 19 is provided on the back side of the casing 11a in the front and back direction of the vehicle. In other words, the protrusion 19 is provided on the lower surface 115 so as to surround the back portion of the gasket 14. In FIG. 5, a thick arrow line R schematically represents a path of water. Water droplets that have traveled from the back surface 113 (or lateral surfaces) of the casing 11a to the lower surface 115 thereof cannot overcome the protrusion 19 and fall. The protrusion 19 prevents water droplets that have traveled from the back surface 113 (or the lateral surfaces) to the lower surface 115 from reaching the gasket 14.

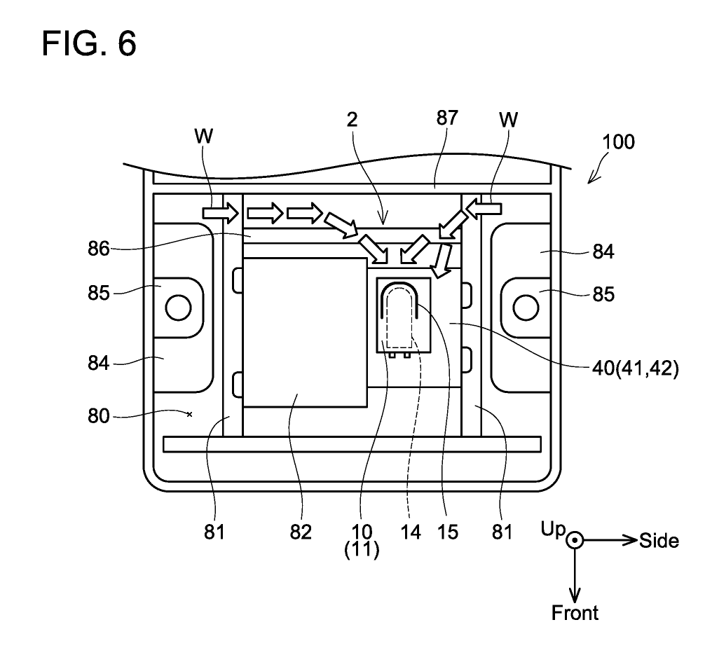

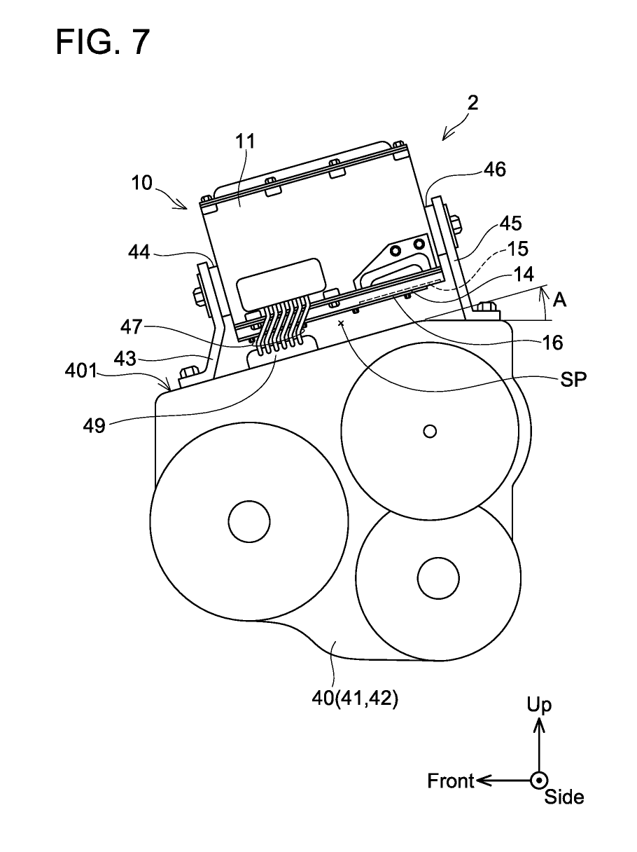

Referring to FIGS. 6 and 7, a vehicle-mounted structure 2 of the power control device 10 will be described below. FIG. 6 is a plan view of a front compartment 80 of a hybrid vehicle 100. The front compartment 80 means a space ahead of a cowl panel 87 that partitions a cabin and the front compartment 80 from each other.

The power control device 10 is fixed above a transaxle 40. The transaxle 40 accommodates a traction motor 41 and a gear set 42. Thus, the transaxle 40 can also be referred to as a housing of the traction motor 41.

An engine 82 is coupled to a lateral side of the transaxle 40. The transaxle 40 and the engine 82 are suspended on a pair of side members 81 extending in the front and back direction of the vehicle on the lower side of the front compartment 80. Fender aprons 84 and suspension towers 85 covering the front tires (not shown) are disposed on the outer side of the transaxle 40 and the engine 82 in the vehicle width direction. A cross member 86 that couples the pair of side members 81 is disposed behind the engine 82 and the transaxle 40.

In the hybrid vehicle 100 during driving, most of water splashed by the front tires is blocked by the fender aprons 84, but some of the water splashes up into the front compartment 80 from the cross member 86 and the sides of the side members 81. Arrows W schematically show a path of water that has entered the front compartment. As indicated by the arrows W in the drawing, the water that has entered the front compartment 80 is directed from the back toward the power control device 10. Water adhering to the back surface or the lateral surfaces of the casing 11 in the power control device 10 travels to the lower surface of the casing 11.

FIG. 6 is a plan view, in which the gasket 14 interposed between the lower surface of the casing 11 and the cover 16 is indicated by a dashed line, and the groove 15 is indicated by a thick line. The groove 15 is provided in the lower surface 115 between the gasket 14 and the outer edge of the lower surface 115. The groove 15 extends along the outer periphery of the back portion of the gasket 14. The groove 15 arranged as described above prevents water, which adheres to the casing 11 from the back side, from reaching the gasket 14. The same effect can also be obtained by providing the protrusion 19 shown in FIG. 5, in place of the groove 15.

FIG. 7 shows a side view of the power control device 10 fixed above the transaxle 40. The power control device 10 is fixed above the transaxle 40 accommodating therein the traction motor 41 and the gear set 42 via brackets 43 and 45. The power control device 10 is fixed to the upper surface 401 of the transaxle 40 with a spacing SP between the upper surface 401 and the power control device 10. The reason why the power control device 10 is not in direct contact with the transaxle 40 is to reduce vibration of the transaxle 40 transmitted to the power control device 10. An antivibration bush 44 is interposed between the bracket 43 and the casing 11 of the power control device 10, and an antivibration bush 46 is interposed between the bracket 45 and the casing 11. The antivibration bushes 44 and 46 attenuate vibrations transmitted to the casing 11.

As mentioned above, the lower cover 16 is attached to the lower surface of the casing 11 of the power control device 10, and the gasket 14 is interposed between the lower cover 16 and the lower surface of the casing 11.

An upper surface 401 of the transaxle 40 is inclined forward and downward at an angle A. The angle A is in a range from 10 to 30 degrees. Since the upper surface 401 is inclined forward and downward, the casing 11 of the power control device 10, supported above the upper surface 401, is also inclined forward and downward. The spacing SP is secured between the casing 11 and the upper surface 401, so that water from the back side is more likely to adhere to the gasket 14. In the vehicle-mounted structure 2 of the embodiment, the groove 15 is provided along the outer periphery of the back portion of the gasket 14. Water droplets (or salt water) that have adhered to the casing 11 from the back side and have traveled to the lower surface are prevented by the groove 15 from reaching the gasket 14.

Some of the features of the techniques described in the embodiments will be summarized below. The cooling medium flow channel 12 is provided in the lower portion (lower surface 115) of the casing 11 in the power control device 10. The lower cover 16 for closing the cooling medium flow channel 12 is attached to the lower surface of the casing 11. The lower cover 16 is attached to the lower surface 115 with the gasket 14 interposed between the lower cover 16 and the lower surface 115. The gasket 14 is disposed on the lower surface 115 so as to surround the cooling medium flow channel 12. The groove 15 or protrusion 19 is provided on the lower surface 115 of the casing 11 at a position between the gasket 14 and the outer edge 115a of the lower surface 115. The groove 15 or protrusion 19 prevents water from adhering to the gasket 14.

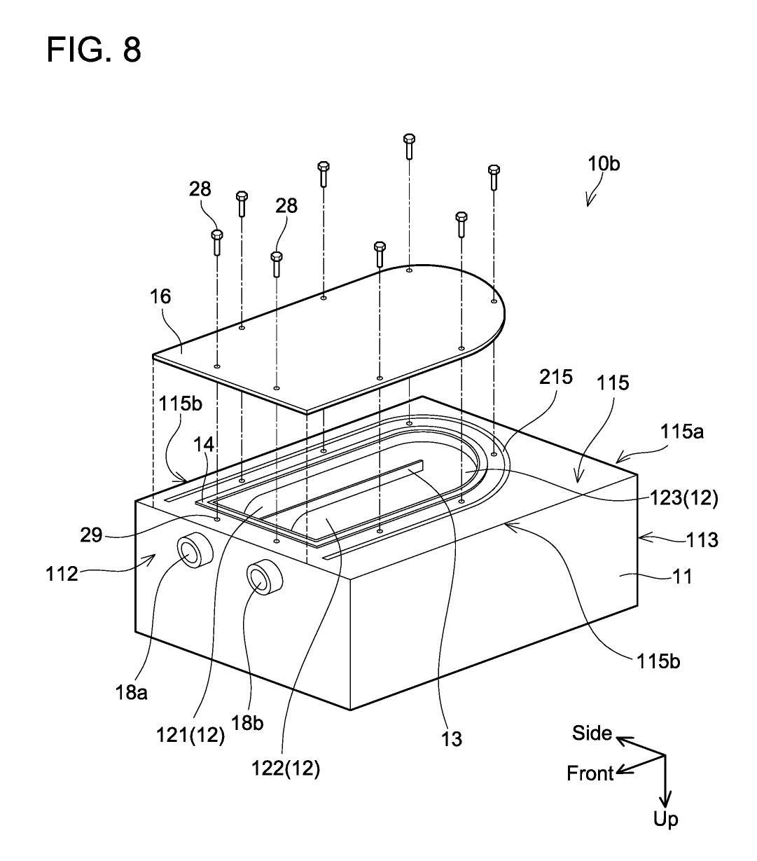

The power control device 10 is mounted in the front compartment 80 of the vehicle. The groove 15 or protrusion 19 is provided on the lower surface of the casing 11 at a position between the gasket 14 and the outer edge 115a of the lower surface 115 on the back side of the casing in the front and back direction of the vehicle. The groove 15 or protrusion 19 may be provided not only between the gasket 14 and the outer edge 115a of the lower surface 115 on the back side of the casing, but also between the gasket and the outer edges of the lower surface of the casing in the lateral direction of the vehicle. FIG. 8 is a perspective view of a power control device 10b in another variant as viewed obliquely from below. The power control device 10b is provided with a groove 215 between the gasket 14 and the outer edge of the lower surface 115, specifically, from the outer edge 115a of the back portion of the lower surface 115 to outer edges 115b of the lower surface 115 in the lateral direction. The power control device 10b can also prevent water that has traveled from the lateral surfaces of the casing 11 in the vehicle lateral direction to the lower surface of the casing 11 from adhering to the gasket 14.

Attention will be given to the techniques described in the embodiment. The groove 15 or protrusion 19 may be provided to surround the gasket 14. The groove 15 or protrusion 19 is not limited to one groove 15 or protrusion 19 formed continuously, and alternatively may be constituted of a plurality of grooves or protrusions interspersed along the gasket 14.

Specific examples of the present invention have been described in detail, however, these are mere exemplary indications and thus do not limit the scope of the claims. The art described in the claims include modifications and variations of the specific examples presented above. Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

What is claimed is:

1. A power control device comprising;
a cooling medium flow channel provided on a lower portion of a casing of the power control device;
a cover attached to a lower surface of the casing with a gasket interposed between the cover and the lower surface, the gasket surrounding the cooling medium flow channel, the cover closing the cooling medium flow channel; and
a groove or a protrusion provided on the lower surface at a position between the gasket and an outer edge of the lower surface.

2. A structure of mounting the power control device as in claim 1, wherein
the power control device is mounted in a front compartment of a vehicle, and
the groove or the protrusion is provided on the lower surface at a position between the gasket and the outer edge of the lower surface on a back side of the casing in a front and back direction of the vehicle.
